(19) United States
(12) Patent Application Publication
(10) Pub. No.: US 2025/0081460 A1
(43) Pub. Date: Mar. 6, 2025

(54) MICROELECTRONIC DEVICES, AND RELATED METHODS AND MEMORY DEVICES

(71) Applicant: Micron Technology, Inc., Boise, ID (US)

(72) Inventors: Albert Fayrushin, Boise, ID (US); Haitao Liu, Boise, ID (US); Kunal R. Parekh, Boise, ID (US)

(21) Appl. No.: 18/745,922

(22) Filed: Jun. 17, 2024

Related U.S. Application Data
(60) Provisional application No. 63/580,944, filed on Sep. 6, 2023.

(51) Int. Cl. H10B 43/27; H10B 41/27; H10B 41/35; H10B 43/35

(52) U.S. Cl. CPC H10B 43/27; H10B 41/27; H10B 41/35; H10B 43/35

(57) ABSTRACT

A microelectronic device includes a stack structure, a cell pillar structure, doped semiconductor material, and control logic devices. The stack structure includes vertically neighboring tiers respectively including a conductive structure and an insulative structure vertically neighboring the conductive structure. The cell pillar structure vertically extends through the stack structure and includes a fill material, a channel material horizontally surrounding the fill material, and an outer material stack horizontally surrounding the channel material. The doped semiconductor material vertically overlies the stack structure and includes a first portion substantially continuously horizontally extending over the stack structure and the cell pillar structure, and a second portion vertically projecting from the first portion and in physical contact with the channel material of the cell pillar structure. The control logic devices vertically underlie and are coupled to the cell pillar structures. Related methods, memory devices, and electronic systems are also described.

### CROSS-REFERENCE TO RELATED APPLICATION

This application claims the benefit under 35 U.S.C. § 119(e) of U.S. Provisional Patent Application Ser. No. 63/580,944, filed Sep. 6, 2023, the disclosure of which is hereby incorporated herein in its entirety by this reference.

### TECHNICAL FIELD

The disclosure, in various embodiments, relates generally to the field of microelectronic device design and fabrication. More specifically, the disclosure relates to methods of forming microelectronic devices, and to related microelectronic devices, memory devices, electronic systems, and additional methods.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified designs.

One example of a microelectronic device is a memory device. Memory devices are generally provided as internal integrated circuits in computers or other electronic devices. There are many types of memory devices including, but not limited to, non-volatile memory devices (e.g., NAND Flash memory devices). One way of increasing memory density in non-volatile memory devices is to utilize vertical memory array (also referred to as a “three-dimensional (3D) memory array”) architectures. A conventional vertical memory array includes vertical memory strings extending through openings in one or more decks (e.g., stack structures) including tiers of conductive structures and dielectric materials. Each vertical memory string may include at least one select device coupled in series to a serial combination of vertically stacked memory cells. Such a configuration permits a greater number of switching devices (e.g., transistors) to be located in a unit of die area (i.e., length and width of active surface consumed) by building the array upwards (e.g., vertically) on a die, as compared to structures with conventional planar (e.g., two-dimensional) arrangements of transistors.

Control logic devices within a control logic region of a memory device underlying or overlying a memory array of the memory device (e.g., a non-volatile memory device) have been used to control operations (e.g., access operations, read operations, write operations, erase operations) on the memory cells of the memory device. An assembly of the control logic devices may be provided in electrical communication with the memory cells of the memory array by way of routing and interconnect structures. However, processing conditions (e.g., temperatures, pressures, materials) and/or designs for the formation of the memory array over the control logic region can limit the configurations and performance of the control logic devices within the control logic region; or processing conditions and/or designs for the formation of the control logic region outside horizontal boundaries of the memory array can limit the configurations and performance of features of the memory array. In addition, conventional memory device configurations can also be complex and costly to manufacture, can impede reductions to the size (e.g., horizontal footprint) of a memory device, and/or can impede improvements in the performance (e.g., faster memory cell ON/OFF speed, lower threshold switching voltage requirements, faster data transfer rates, lower power consumption) of the memory device.

### BRIEF DESCRIPTION OF THE DRAWINGS

FIGS. 1A through 1F are simplified, partial vertical cross-sectional views illustrating a method of forming a microelectronic device, in accordance with embodiments of the disclosure.

FIG. 2 is a simplified, partial vertical cross-sectional view of a microelectronic device, in accordance with additional embodiments of the disclosure.

FIG. 3 is a simplified, partial vertical cross-sectional view of a microelectronic device, in accordance with further embodiments of the disclosure.

FIG. 4 is a schematic block diagram of an electronic system, in accordance with embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device, such as 3D NAND Flash memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional volatile memory, such as conventional dynamic random access memory (DRAM); conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, structures, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “above,” “upper,” “top,” “front,” “rear,” “left,” “right,” and the like, may be used for case of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10-8 Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials. In addition, a “semiconductor structure” or a “semiconductor structure” means and includes a structure formed of and including semiconductor material.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

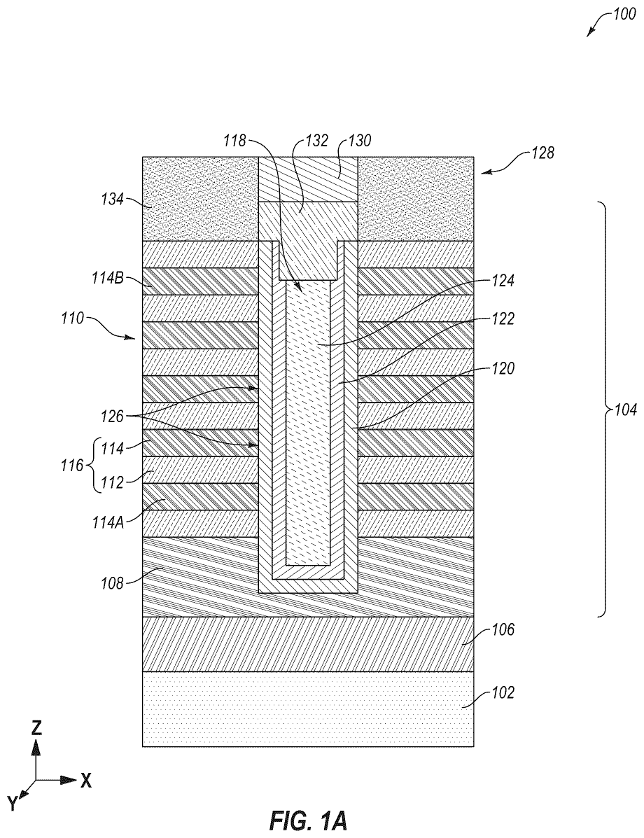

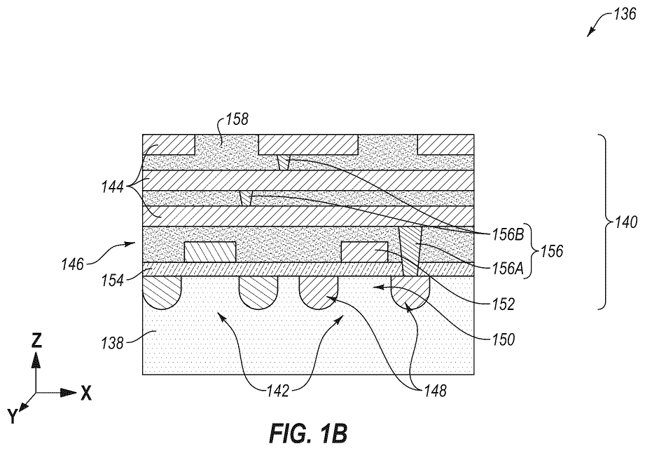

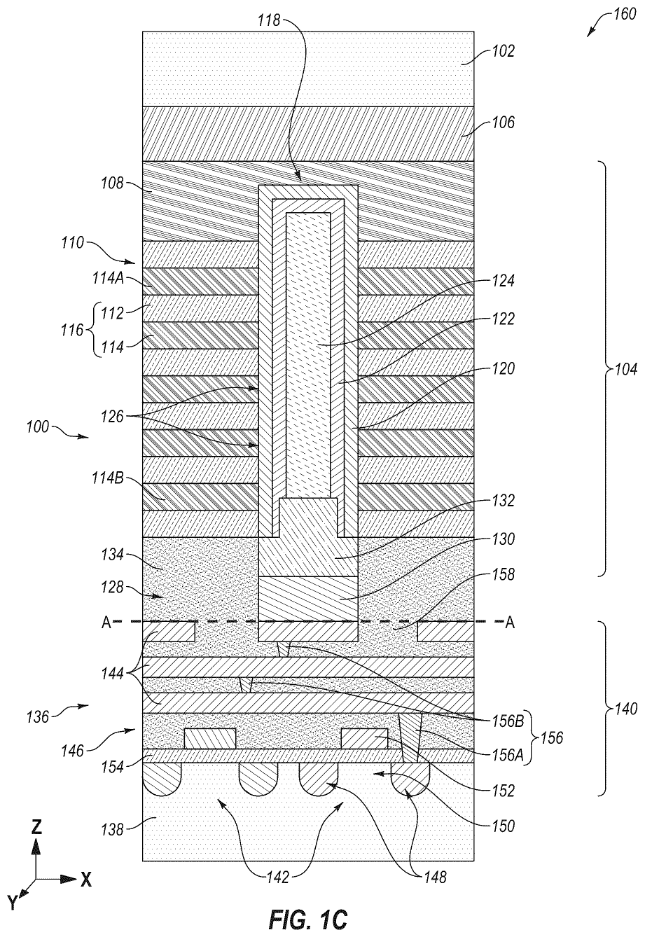

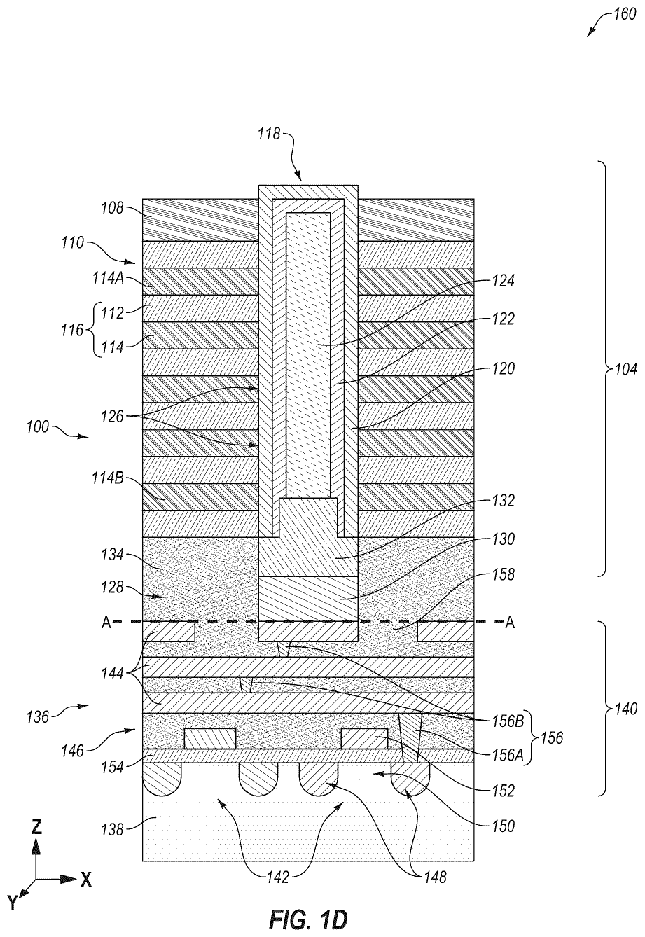

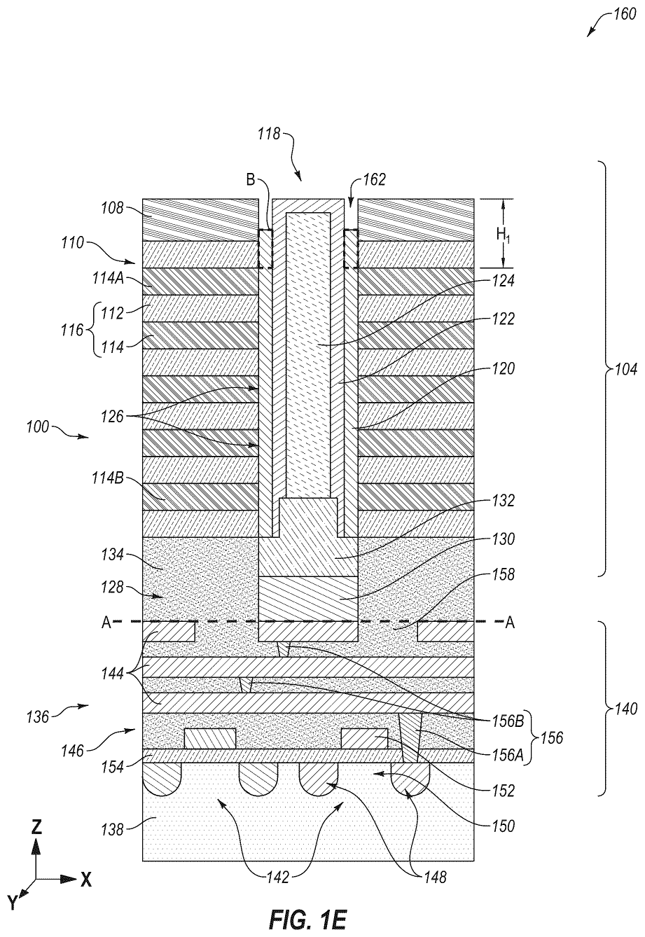

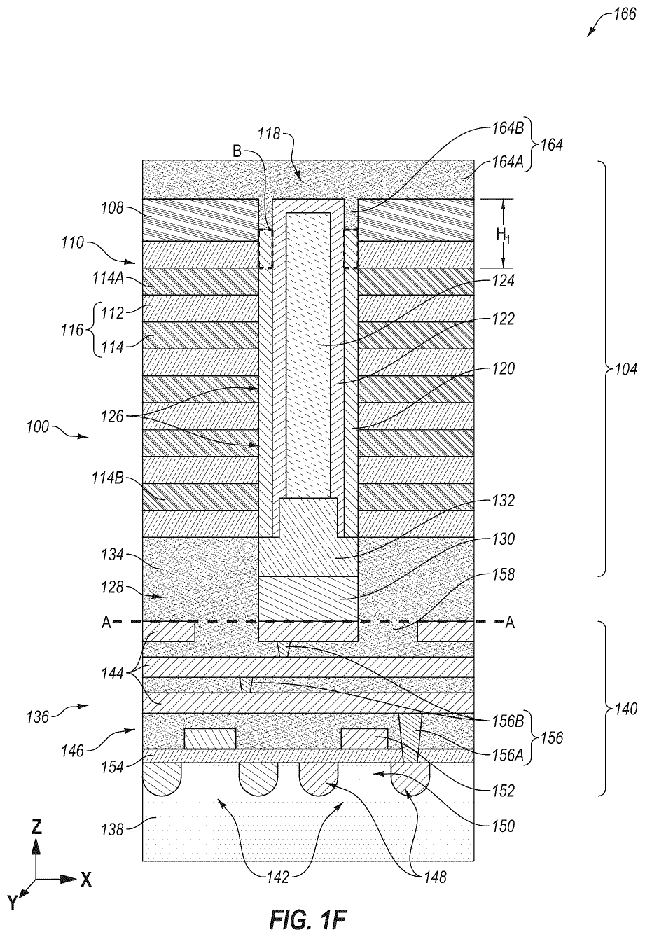

FIGS. 1A through IF are simplified, partial vertical cross-sectional views illustrating embodiments of a method of forming a microelectronic device (e.g., a memory device, such as a 3D NAND Flash memory device). With the description provided below, it will be readily apparent to one of ordinary skill in the art that the methods and structures described herein may be used to form various devices and electronic systems.

Referring to FIG. 1A, a first microelectronic device structure 100 (e.g., a first wafer, a memory array wafer) may be formed to include a base structure 102, and a memory array region 104 over the base structure 102. The memory array region 104 includes a first isolation material 106 on or over the base structure 102; doped semiconductor material 108 on or over the first isolation material 106; a stack structure 110 on or over the doped semiconductor material 108; cell pillar structures 118 vertically extending (e.g., in the Z-direction) through the stack structure 110 and into the doped semiconductor material 108; at least one conductive routing tier 128 overlying the stack structure 110, and including conductive routing structures 130 coupled to the cell pillar structures 118; and a second isolation material 134 on or over the stack structure 110 and at least partially surrounding (e.g., horizontally surrounding) the conductive routing structures 130. A source side of the memory array region 104 may be considered to be a first vertical boundary (e.g., a first end) most proximate to the doped semiconductor material 108, and a drain side of the memory array region 104 may be considered to be a second vertical boundary (e.g., a second end) most proximate to the conductive routing tier 128 including the conductive routing structures 130. The first microelectronic device structure 100 (including the base structure 102 and the memory array region 104 thereof) also includes additional features (e.g., structures, materials, devices), as described in further detail below.

The base structure 102 of the first microelectronic device structure 100 comprises a base material or construction upon which additional features (e.g., materials, structures, devices) of the first microelectronic device structure 100 are formed. The base structure 102 may, for example, be formed of and include one or more of semiconductor material, a base semiconductor material on a supporting structure, glass material (e.g., one or more of borosilicate glass (BSP), phosphosilicate glass (PSG), fluorosilicate glass (FSG), borophosphosilicate glass (BPSG), aluminosilicate glass, an alkaline earth boro-aluminosilicate glass, quartz, titania silicate glass, and soda-lime glass), and ceramic material (e.g., one or more of poly-aluminum nitride (p-AlN), silicon on poly-aluminum nitride (SOPAN), aluminum nitride (AlN), aluminum oxide (e.g., sapphire; α-Al₂O₃), and silicon carbide). The base structure 102 may be configured to facilitate safe handling of the first microelectronic device structure 100 for subsequent attachment to a second microelectronic device structure, as described in further detail below. In some embodiments, the base structure 102 is a semiconductor structure (e.g., a silicon structure, such a polycrystalline silicon structure). In additional embodiments, the base structure 102 is one of a glass structure and a ceramic structure. The base structure 102 may include one or more layers, structures, and/or regions formed therein and/or thereon.

The first isolation material 106 may be formed of and include insulative material. By way of non-limiting example, the first isolation material 106 may be formed of and include one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and a MgOₓ), at least one dielectric nitride material (e.g., SiN_{y}), at least one dielectric oxynitride material (e.g., SiOₓN_{y}), at least one dielectric oxycarbide material (e.g., SiOₓC_{y}), at least one hydrogenated dielectric oxycarbide material (e.g., SiCₓO_{y}H_{z}), and at least one dielectric carboxynitride material (e.g., SiOₓC_{z}N_{y}). In some embodiments, the first isolation material 106 is formed of and includes dielectric oxide material (e.g., SiOₓ, such as SiO₂). The first isolation material 106 may be substantially homogeneous, or the first isolation material 106 may be heterogeneous.

The doped semiconductor material 108 may be formed of and include semiconductor material doped (e.g., impregnated) with one or more conductivity enhancing species (e.g., one or more N-type dopants, one or more P-type dopants). In some embodiments, the doped semiconductor material 108 is formed of and includes polycrystalline silicon (also referred to herein as “polysilicon”) doped (e.g., relatively highly doped) with at least one N-type dopant (e.g., one or more of phosphorus, arsenic, antimony, and bismuth). For example, the doped semiconductor material 108 may be formed of and include N+ polysilicon. In additional embodiments, the doped semiconductor material 108 is formed of and includes polycrystalline silicon doped (e.g., relatively highly doped) with at least one P-type dopant (e.g., one or more of boron, aluminum, and gallium).

The first microelectronic device structure 100 may be formed to be free of (e.g., to not include) any conductive, lateral contact structure interposed between the base structure 102 and the stack structure 110 (e.g., between the doped semiconductor material 108 and the stack structure 110), wherein the cell pillar structures 118 vertically extend completely through the conductive, lateral contact structure and channel material 122 (described in further detail below) of individual cell pillar structures 118 contacts (e.g., physically contacts, electrically contacts) the conductive, lateral contact structure. The omission (e.g., absence) of such a conductive, lateral contact structure may decrease processing complexity and increase production efficiency as compared to conventional methods and conventional designs employing such a conductive, lateral contact structure.

Still referring to FIG. 1A, the stack structure 110 within the memory array region 104 includes a vertically alternating (e.g., in the Z-direction) sequence of insulative structures 112 and conductive structures 114 arranged in tiers 116. Each of the tiers 116 of the stack structure 110 may include at least one of the conductive structures 114 vertically neighboring at least one of the insulative structures 112. In some embodiments, the conductive structures 114 are respectively formed of and include tungsten (W) and the insulative structures 112 are respectively formed of and include SiO₂. In additional embodiments, the conductive structures 114 are respectively formed of and include a different conductive material (e.g., semiconductor material doped with at least one conductivity enhancing dopant; a different metal; an alloy; a conductive metal-containing material), and/or the insulative structures 112 are respectively formed of and include a different insulative material (e.g., a different dielectric oxide material, a dielectric nitride material, a dielectric oxynitride material, a dielectric oxycarbide material, a hydrogenated dielectric oxycarbide material, a dielectric carboxynitride material). The conductive structures 114 and insulative structures 112 of the tiers 116 of the stack structure 110 may each exhibit a desired vertical thickness (e.g., vertical dimension in the Z-direction). As shown in FIG. 1A, the insulative structure 112 of a vertically lowermost tier 116 of the stack structure 110 may be vertically interposed between the doped semiconductor material 108 and the conductive structure 114 of the vertically lowermost tier 116 of the stack structure 110. An individual insulative structure 112 of the vertically lowermost tier 116 of the stack structure 110 may vertically extend from an upper boundary (e.g., an upper surface, a top surface) of the doped semiconductor material 108 to a lower boundary (e.g., a lower surface, a bottom surface) of an individual conductive structure 114 of the vertically lowermost tier 116 of the stack structure 110.

Optionally, one or more liner materials (e.g., insulative liner material(s), conductive liner material(s)) may be formed around the conductive structures 114 of the stack structure 110. The liner material(s) may, for example, be formed of and include one or more of a metal (e.g., titanium, tantalum), an alloy, a metal nitride (e.g., tungsten nitride, titanium nitride, tantalum nitride), and a metal oxide (e.g., aluminum oxide). In some embodiments, the liner material(s) comprise at least one additional conductive material employed as a seed material for the formation of the conductive structures 114. In some embodiments, the liner material(s) comprise titanium nitride (TiN_{y}). In further embodiments, the liner material(s) further include aluminum oxide (AlOₓ). As a non-limiting example, AlOₓ may be formed directly adjacent the insulative structures 112, TiN_{y} may be formed directly adjacent the AlOₓ, and W may be formed directly adjacent the TiN_{y}. For clarity and ease of understanding the description, the liner material(s) are not illustrated in FIG. 1A, but it will be understood that the liner material(s) may be disposed around the conductive structures 114.

Still referring to FIG. 1A, the conductive structures 114 of the stack structure 110 may include one or more first conductive structures 114A within one or more relatively vertically lower tier(s) 116 (e.g., at least a relatively vertically lowest tier 116) of the stack structure 110, and one or more second conductive structures 114B within one or more relatively vertically higher tier(s) 116 (e.g., at least a relatively vertically highest tier 116) of the stack structure 110. The first conductive structures 114A may be employed as source-side gate-induced drain-leakage (GIDL) generation (GG) structures. The second conductive structures 114B may be employed as drain-side GG structures. In addition, conductive structure(s) 114 of the stack structure 110 within one or more additional tiers 116 of the stack structure 110 proximate the first conductive structures 114A (e.g., source-side GG structures) may be employed as source-side select gate (SGS) structure(s) of the memory array region 104; and conductive structure(s) 114 of the stack structure 110 within one or more further tiers 116 of the stack structure 110 proximate the second conductive structures 114B (e.g., drain-side GG structures) may be employed as drain-side select gate (SGD) structure(s) of the memory array region 104. Furthermore, at least some of the conductive structure(s) 114 of the stack structure 110 within one or more yet further tiers 116 of the stack structure 110 may be employed as local word line structures (e.g., local access line structures) of the memory array region 104.

With continued reference to FIG. 1A, the cell pillar structures 118 may each individually be formed of and include multiple (e.g., a plurality) materials facilitating the formation of vertically extending (e.g., in the Z-direction) strings of memory cells 126 within the memory array region 104. By way of non-limiting example, each of the cell pillar structures 118 may individually be formed to include an outer material stack 120, channel material 122 inwardly horizontally adjacent the outer material stack 120, and fill material 124 inwardly horizontally adjacent the channel material 122.

The outer material stack 120 of respective cell pillar structures 118 may include charge-blocking material, such as first dielectric oxide material (e.g., SiOₓ, such as SiO₂; AlOₓ, such as Al₂O₃); charge-trapping material, such as dielectric nitride material (e.g., SiN_{y}, such as Si₃N₄); and tunnel dielectric material, such as second oxide dielectric material (e.g., SiOₓ, such as SiO₂). The tunnel dielectric material may be outwardly horizontally surrounded by the charge-trapping material; and the charge-trapping material may be outwardly horizontally surrounded by the charge-blocking material. In some embodiments, the outer material stack 120 of respective cell pillar structures 118 comprises an oxide-nitride-oxide (ONO) stack.

The channel material 122 of respective cell pillar structures 118 may be formed of and include one or more of semiconductor material. In some embodiments, the channel material 122 is formed of and includes semiconductor material (e.g., polycrystalline silicon) doped with at least one P-type dopant (e.g., one or more of boron, aluminum, and gallium) or at least one N-type dopant (e.g., one or more of phosphorus, arsenic, antimony, and bismuth), at an atomic dopant concentration less than or equal to about 1.0e17 dopant atoms per cubic centimeter. In additional embodiments, the channel material 122 is formed of and includes semiconductor material (e.g., polycrystalline silicon) doped with at least one P-type dopant or at least one N-type dopant, at an atomic concentration greater than about 1.0e17 dopant atoms per cubic centimeter. In further embodiments, the channel material 122 comprises an undoped semiconductor material (e.g., undoped polycrystalline silicon). In still further embodiments the channel material 122 is formed of at least one oxide semiconductor material having a band gap larger than that polycrystalline silicon, such as a band gap larger than 1.65 electronvolts (cV). By way of non-limiting example, the channel material 122 may be formed of and include one or more of ZnₓSn_{y}O, InₓZn_{y}O, ZnₓO, InₓGa_{y}Zn_{z}O, InₓGa_{y}Si_{z}O, InₓW_{y}O, InₓO, SnₓO, TiₓO, ZnₓON_{z}, MgₓZn_{y}O, ZrₓIn_{y}Zn_{z}O, HfₓIn_{y}Zn_{z}O, SnₓIn_{y}Zn_{z}O, AlₓSn_{y}In_{z}ZnₐO, SiₓIn_{y}Zn_{z}O, AlₓZn_{y}Sn_{z}O, GaₓZn_{y}Sn_{z}O, ZrₓZn_{y}Sn_{z}O, and other similar materials. The channel material 122 may be substantially homogeneous, or the channel material 122 may be heterogeneous. As shown in FIG. 1A, the channel material 122 of an individual cell pillar structure 118 may be outwardly horizontally surrounded by the outer material stack 120 (e.g., tunnel dielectric material of the outer material stack 120) of the cell pillar structure 118.

The fill material 124 of respective cell pillar structures 118 may be formed of and include dielectric material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and a MgOₓ), at least one dielectric nitride material (e.g., SiN_{y}), at least one dielectric oxynitride material (e.g., SiOₓN_{y}), at least one dielectric oxycarbide material (e.g., SiOₓC_{y}), at least one hydrogenated dielectric oxycarbide material (e.g., SiCₓO_{y}H_{z}), at least one dielectric carboxynitride material (e.g., SiOₓC_{z}N_{y}), and air. In some embodiments, the fill material 124 is formed of and includes dielectric oxide material (e.g., SiOₓ, such as SiO₂). In additional embodiments, the fill material 124 is formed of and includes dielectric nitride material (e.g., SiN_{y}, such as Si₃N₄). The fill material 124 may be substantially homogeneous, or the fill material 124 may be heterogeneous. As shown in FIG. 1A, the fill material 124 of an individual cell pillar structure 118 is outwardly horizontally surrounded by the channel material 122 of the cell pillar structure 118.

As shown in FIG. 1A, lower vertical boundaries (e.g., in the Z-direction) of the cell pillar structures 118 may be positioned within vertical boundaries of the doped semiconductor material 108. The outer material stack 120 (e.g., the charge-trapping material thereof) of an individual cell pillar structure 118 may physically contact the doped semiconductor material 108 at outer horizontal boundaries and lower vertical boundaries of the cell pillar structure 118. As previously discussed, the first microelectronic device structure 100 may be free of (e.g., does not include) any conductive, lateral contact structure in contact (e.g., physical contact, electrical contact) with the channel material 122 of a respective cell pillar structure 118 thereof (e.g., horizontally extending through the outer material stack 120 of the cell pillar structure 118 and to the channel material 122 of the cell pillar structure 118) and vertically interposed between the base structure 102 and the stack structure 110 (e.g., vertically between the doped semiconductor material 108 and the stack structure 110).

Intersections of the cell pillar structures 118 and the conductive structures 114 of some of the tiers 116 of the stack structure 110 may define vertically extending strings of memory cells 126 coupled in series with one another within the memory array region 104 of the first microelectronic device structure 100. In some embodiments, the memory cells 126 formed at the intersections of some of the conductive structures 114 and the cell pillar structures 118 comprise so-called “MONOS” (metal-oxide-nitride-oxide-semiconductor) memory cells. In additional embodiments, the memory cells 126 comprise so-called “TANOS” (tantalum nitride-aluminum oxide-nitride-oxide-semiconductor) memory cells, or so-called “BETANOS” (band/barrier engineered TANOS) memory cells, each of which are subsets of MONOS memory cells. In further embodiments, the memory cells comprise so-called “floating gate” memory cells including floating gates (e.g., metallic floating gates) as charge storage structures. The floating gates may horizontally intervene between central structures of the cell pillar structures 118 and the conductive structures 114 of some of the tiers 116 of the stack structure 110.

Still referring to FIG. 1A, the conductive routing structures 130 of the conductive routing tier 128 may vertically overlie the cell pillar structures 118 (and, hence, the vertically extending strings of memory cells 126). At least some of the conductive routing structures 130 may be coupled to the cell pillar structures 118 and may be employed as digit line structures (e.g., bit line structures, data line structures) for the memory array region 104 of the first microelectronic device structure 100. Conductive routing structures 130 employed as digit line structures may exhibit horizontally elongate shapes extending in parallel in the Y-direction. As used herein, the term “parallel” means substantially parallel. The conductive routing structures 130 may individually be formed of and include conductive material, and may respectively be substantially homogeneous or heterogeneous. In some embodiments, the conductive routing structures 130 are individually formed of and include one or more of W, Ru, Mo, and TiN_{y}.

With continued reference to FIG. 1A, contact structures 132 may be formed to vertically extend between and couple some of the conductive routing structures 130 and the cell pillar structures 118 (and, hence, the vertically extending strings of memory cells 126). The contact structures 132 may contact (e.g., physically contact, electrically contact) the channel material 122 of the cell pillar structures 118. In some embodiments, portions of the contact structures 132 vertically extend into the cell pillar structures 118. As shown in FIG. 1A, for an individual contact structure 132, a vertically lower portion of the contact structure 132 may vertically extend (e.g., in the Z-direction) beyond uppermost vertical boundaries (e.g., uppermost surfaces) of the channel material 122 of a respective cell pillar structure 118, and may be horizontally surrounded by and contact (e.g., physically contact, electrically contact) the channel material 122 of the cell pillar structure 118 at inner horizontal boundaries (e.g., inner sidewalls) of the channel material 122. In addition, for an individual contact structures 132, a vertically upper portion of the contact structure 132 may vertically overlie the vertically lower portion of the contact structure 132, and may be located vertically above uppermost boundaries of the cell pillar structure 118 (e.g., uppermost boundaries of the channel material 122 and the outer material stack 120 of the cell pillar structure 118). As shown in FIG. 1A, the vertically upper portion of an individual contact structure 132 may horizontally extend beyond horizontal boundaries of the vertically lower portion of the contact structure 132, and may contact (e.g., physically contact, electrically contact) the channel material 122 of an individual cell pillar structure 118 at the uppermost boundary (e.g., upper surface, top surface) of the channel material 122.

The contact structures 132 may be formed of and include conductive material. A material composition of the contact structures 132 may be substantially the same as a material composition of the conductive routing structures 130, or the material composition of the contact structures 132 may be different than the material composition of the conductive routing structures 130. As a non-limiting example, at least a portion (e.g., at least the vertically lower portion) of each of the contact structures 132 may be formed of and include a conductively-doped semiconductor material (e.g., conductively-doped polycrystalline silicon). As another non-limiting example, at least a portion (e.g., at least the vertically upper portion) of each of the contact structures 132 may be formed of and include a metal material comprising one or more of at least one metal, at least one alloy, and at least one conductive metal-containing material (e.g., a conductive metal nitride, a conductive metal silicide, a conductive metal carbide, a conductive metal oxide). Each of the contact structures 132 may individually be substantially homogeneous, or one or more of the contact structures 132 may individually be substantially heterogeneous.

Still referring to FIG. 1A, the second isolation material 134 may be formed of and include insulative material. A material composition of the second isolation material 134 may be substantially the same as a material composition of the first isolation material 106, or the material composition of the second isolation material 134 may be different than the material composition of first isolation material 106. By way of non-limiting example, the second isolation material 134 may be formed of and include one or more of dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and a MgOₓ), dielectric nitride material (e.g., SiN_{y}), dielectric oxynitride material (e.g., SiOₓN_{y}), dielectric oxycarbide material (e.g., SiOₓC_{y}), hydrogenated dielectric oxycarbide material (e.g., SiCₓO_{y}H_{z}), and dielectric carboxynitride material (e.g., SiOₓC_{z}N_{y}). In some embodiments, the second isolation material 134 is formed of and includes dielectric oxide material (e.g., SiOₓ, such as SiO₂). In additional embodiments, the second isolation material 134 is formed of and includes low-K dielectric material, such as one or more of SiOₓC_{y}, SiOₓ N_{y}, SiCₓO_{y}H_{z}, and SiOₓC_{z}N_{y}. The second isolation material 134 may be substantially homogeneous, or the second isolation material 134 may be heterogeneous.

Referring to FIG. 1B, a second microelectronic device structure 136 (e.g., a second wafer, a control logic wafer) to subsequently be attached to the first microelectronic device structure 100 (FIG. 1A) may be formed. The second microelectronic device structure 136 may be formed to include a base semiconductor structure 138, transistors 142, additional conductive routing structures 144, additional contact structures 156, and third isolation material 158. The second microelectronic device structure 136 may form a control logic region 140 of a microelectronic device to subsequently be formed using the second microelectronic device structure 136 and the first microelectronic device structure 100 (FIG. 1A), as described in further detail below. Portions of the base semiconductor structure 138, the transistors 142, the additional conductive routing structures 144, and the additional contact structures 156 of the second microelectronic device structure 136 form various control logic devices 146 of the control logic region 140, as also described in further detail below.

The base semiconductor structure 138 (e.g., semiconductor wafer) of the second microelectronic device structure 136 comprises a base material or construction upon which additional features (e.g., materials, structures, devices) of the second microelectronic device structure 136 are formed. The base semiconductor structure 138 may comprise a semiconductor structure, or a base semiconductor material on a supporting structure. For example, the base semiconductor structure 138 may comprise a conventional silicon substrate, or another bulk substrate comprising a semiconductor material. In some embodiments, the base semiconductor structure 138 is a silicon structure, such a polycrystalline silicon structure. The base semiconductor structure 138 may include one or more layers, structures, and/or regions formed therein and/or thereon.

As shown in FIG. 1B, the transistors 142 of the control logic region 140 may be formed to be vertically interposed between the additional conductive routing structures 144 and underlying portions of the base semiconductor structure 138. The transistors 142 may be formed to include conductively doped regions 148 (e.g., serving as source regions and drain regions of the transistors 142) within the base semiconductor structure 138, channel regions 150 within the base semiconductor structure 138 and respectively horizontally interposed (e.g., in the X-direction) between two (2) of the conductively doped regions 148, and gate structures 152 (e.g., gate electrodes) vertically overlying the channel regions 150. In addition, the second microelectronic device structure 136 may be formed to include dielectric material 154 (e.g., dielectric oxide material, such as SiO₂) vertically interposed between the gate structures 152 and the channel regions 150 of the transistors 142. The dielectric material 154 may be employed as dielectric gate material (e.g., dielectric oxide gate material) for the transistors 142, and may at least partially (e.g., substantially) horizontally extend on, over, or within the base semiconductor structure 138. As shown in FIG. 1B, in some embodiments, the dielectric material 154 is shared by multiple transistors 142 of the control logic region 140.

For the transistors 142 of the control logic region 140, the conductively doped regions 148 within the base semiconductor structure 138 may be doped with one or more desired conductivity enhancing species. In some embodiments, the conductively doped regions 148 are doped with at least one N-type dopant (e.g., one or more of phosphorus, arsenic, antimony, and bismuth). In some of such embodiments, the channel regions 150 within the base semiconductor structure 138 are doped with at least one P-type dopant (e.g., one or more of boron, aluminum, and gallium). In some other of such embodiments, the channel regions 150 within the base semiconductor structure 138 are substantially undoped. In additional embodiments, the conductively doped regions 148 are doped with at least one P-type dopant (e.g., one or more of boron, aluminum, and gallium). In some of such additional embodiments, the channel regions 150 within the base semiconductor structure 138 are doped with at least one N-type dopant (e.g., one or more of phosphorus, arsenic, antimony, and bismuth). In some other of such additional embodiments, the channel regions 150 within the base semiconductor structure 138 are substantially undoped.

The gate structures 152 may individually horizontally extend (e.g., in the Y-direction) between and be employed by multiple transistors 142 of the control logic region 140. The gate structures 152 may individually be formed of and include conductive material, and may respectively be substantially homogeneous or heterogeneous. In some embodiments, the gate structures 152 are individually formed of and include one or more of W, Ru, Mo, and TiN_{y}.

Still referring to FIG. 1B, the additional conductive routing structures 144 of the second microelectronic device structure 136 may be formed to vertically overlie (e.g., in the Z-direction) the transistors 142 of the control logic region 140. As shown in FIG. 1B, in some embodiments, the second microelectronic device structure 136 is formed to include multiple tiers of the additional conductive routing structures 144. By way of non-limiting example, the second microelectronic device structure 136 may be formed to include at least two tiers (e.g., at least three tiers) of the additional conductive routing structures 144. One or more of the tiers may vertically neighbor one or more other of the tiers. Different tiers of the additional conductive routing structures 144 may have different configurations (e.g., different features, different feature configurations, different feature arrangements) than one another that together facilitate desirable conductive paths within the second microelectronic device structure 136.

The additional conductive routing structures 144 of the second microelectronic device structure 136 may individually be formed of and include conductive material. By way of non-limiting example, the additional conductive routing structures 144 may individually be formed of and include one or more of at least one metal, at least one alloy, and at least one conductive metal-containing material (e.g., a conductive metal nitride, a conductive metal silicide, a conductive metal carbide, a conductive metal oxide). In some embodiments, the additional conductive routing structures 144 are individually formed of and include Cu. In additional embodiments, the additional conductive routing structures 144 are individually formed of and include W.

Still referring to FIG. 1B, the additional contact structures 156 may include first additional contact structures 156A and second additional contact structures 156B. The first additional contact structures 156A may vertically extend between and couple the transistors 142 to one or more of the additional conductive routing structures 144. The second additional contact structures 156B may vertically extend between and couple one or more of the additional conductive routing structures 144 to one or more other of the additional conductive routing structures 144. The additional contact structures 156 (including the first additional contact structures 156A and second additional contact structures 156B) may individually be formed of and include conductive material. In some embodiments, the additional contact structures 156 are individually formed of and include Cu. In additional embodiments, the additional contact structures 156 are individually formed of and include W. In further embodiments, the first additional contact structures 156A of the additional contact structures 156 are individually formed of and include first conductive material (e.g., W); and the second additional contact structures 156B of the additional contact structures 156 are individually formed of and include a second, different conductive material (e.g., Cu).

As previously mentioned, the transistors 142, the additional conductive routing structures 144, and the additional contact structures 156 form various control logic devices 146 of the control logic region 140. In some embodiments, the control logic devices 146 include complementary-metal-oxide-semiconductor (CMOS) circuitry. The control logic devices 146 may be configured to control various operations of features (e.g., the memory cells 126 (FIG. 1A)) of a microelectronic device (e.g., a memory device, such as a 3D NAND Flash memory device) to subsequently be formed from and using the first microelectronic device structure 100 (FIG. 1A) and the second microelectronic device structure 136 (FIG. 1B), as described in further detail below. As a non-limiting example, the control logic devices 146 may include one or more (e.g., each) of charge pumps (e.g., V_{CCP} charge pumps, V_{NEGWL} charge pumps, DVC2 charge pumps), delay-locked loop (DLL) circuitry (e.g., ring oscillators), V_{dd} regulators, string drivers, page buffers, and various chip/deck control circuitry. As another non-limiting example, the control logic devices 146 may include devices configured to control column operations for arrays (e.g., memory element array(s), access device array(s)) within the memory array region 104 (FIG. 1A) of the first microelectronic device structure 100 (FIG. 1A), such as one or more (e.g., each) of decoders (e.g., local deck decoders, column decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry), I/O devices (e.g., local I/O devices), memory test devices, array multiplexers (MUX), and error checking and correction (ECC) devices. As a further non-limiting example, the control logic devices 146 may include devices configured to control row operations for arrays (e.g., memory element array(s), access device array(s)) within the memory array region 104 (FIG. 1A) of the first microelectronic device structure 100 (FIG. 1A), such as one or more (e.g., each) of decoders (e.g., local deck decoders, row decoders), drivers (e.g., WL drivers), repair circuitry (e.g., row repair circuitry), memory test devices, MUX, ECC devices, and self-refresh/wear leveling devices.

Still referring to FIG. 1B, the third isolation material 158 may cover and surround portions of the transistors 142, the additional conductive routing structures 144, and the additional contact structures 156. The third isolation material 158 may subsequently be attached (e.g., bonded) to the second isolation material 134 (FIG. 1A) of the first microelectronic device structure 100 (FIG. 1A) in the process of forming a microelectronic device (e.g., a memory device) using the first microelectronic device structure 100 (FIG. 1G) and the second microelectronic device structure 136, as described in further detail below. A material composition of the third isolation material 158 may be substantially the same as a material composition of the second isolation material 134 (FIG. 1A), or the material composition of the third isolation material 158 may be different than the material composition of the second isolation material 134 (FIG. 1A). By way of non-limiting example, the second isolation material 134 may be formed of and include one or more of dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and a MgOₓ), dielectric nitride material (e.g., SiN_{y}), dielectric oxynitride material (e.g., SiOₓN_{y}), dielectric oxycarbide material (e.g., SiOₓC_{y}), hydrogenated dielectric oxycarbide material (e.g., SiCₓO_{y}H_{z}), and dielectric carboxynitride material (e.g., SiOₓC_{z}N_{y}). In some embodiments, the third isolation material 158 is formed of and includes dielectric oxide material, such as SiOₓ (e.g., SiO₂). In additional embodiments, the third isolation material 158 is formed of and includes low-K dielectric material, such as one or more of SiOₓC_{y}, SiOₓ N_{y}, SiCₓO_{y}H_{z}, and SiOₓC_{z}N_{y}. The third isolation material 158 may be substantially homogeneous, or the third isolation material 158 may be heterogeneous.

Referring to next to FIG. 1C, following the formation of the first microelectronic device structure 100 and the separate formation of the second microelectronic device structure 136, the first microelectronic device structure 100 may be vertically inverted (e.g., flipped upside down in the Z-direction) and attached (e.g., bonded) to the second microelectronic device structure 136 to form an assembly 160. Alternatively, the second microelectronic device structure 136 may be vertically inverted (e.g., flipped upside down in the Z-direction) and attached to the first microelectronic device structure 100 to form the assembly 160. A front side (also referred to herein as a “face” side) of the first microelectronic device structure 100 may be considered to be a side (e.g., end surface) most proximate to the conductive routing structures 130, and a back side of the first microelectronic device structure 100 may be considered to be an additional side (e.g., additional end surface) relatively more distal from the conductive routing structures 130 (e.g., most proximate to the base structure 102) than the front side. In addition, a front side (also referred to herein as a “face” side) of second microelectronic device structure 136 may be considered to be a side (e.g., end surface) most proximate to the additional conductive routing structures 144, and a back side of the second microelectronic device structure 136 may be considered to be an additional side (e.g., additional end surface) relatively more distal from the additional conductive routing structures 144 (e.g., most proximate to the base semiconductor structure 138) than the front side. Accordingly, in the configuration shown in FIG. 1C, the assembly 160 may be formed to have a “front-to-front” (F2F) (also referred to herein as “face-to-face”) arrangement of the first microelectronic device structure 100 to the second microelectronic device structure 136.

Attaching the first microelectronic device structure 100 to the second microelectronic device structure 136 may couple at least some of conductive routing structures 130 (e.g., digit line structures) of the memory array region 104 to at least some of the additional conductive routing structures 144 of the control logic region 140. Attaching the first microelectronic device structure 100 to the second microelectronic device structure 136 may also attach (e.g., bond) the second isolation material 134 of the first microelectronic device structure 100 to the third isolation material 158 of the second microelectronic device structure 136. In FIG. 1C, vertical boundaries of the first microelectronic device structure 100 relative to the second microelectronic device structure 136 prior to the attachment of the first microelectronic device structure 100 to the second microelectronic device structure 136 to form the assembly 160 are depicted by the dashed line A-A.

The first microelectronic device structure 100 may be attached to the second microelectronic device structure 136 through dielectric-dielectric (e.g., oxide-oxide) bonding alone or through a combination of dielectric-dielectric (e.g., oxide-oxide) bonding and conductor-conductor (e.g., metal-metal) bonding. For example, the first microelectronic device structure 100 and the second microelectronic device structure 136 may be brought into physical contact with one another at an interface, and then the resulting assembly may be exposed to a temperature greater than or equal to about 400° C. (e.g., within a range of from about 400° C. to about 800° C., greater than about 800° C.) at least form dielectric-to-dielectric (e.g., oxide-to-oxide) bonds between the second isolation material 134 of the first microelectronic device structure 100 and the third isolation material 158 of the second microelectronic device structure 136. In some embodiments, the attachment process also forms conductor-to-conductor (e.g., metal-to-metal) bonds between at least some of the conductive routing structures 130 of the first microelectronic device structure 100 and at least some of the additional conductive routing structures 144 of the second microelectronic device structure 136. The first microelectronic device structure 100 may be attached to the second microelectronic device structure 136 without a bond line.

Referring next to FIG. 1D, after attaching the first microelectronic device structure 100 to the second microelectronic device structure 136 to form the assembly 160, the base structure 102 (FIG. 1C), the first isolation material 106, and an upper portion of the doped semiconductor material 108 removed to expose (e.g., uncover) a portion of the outer material stack 120 of respective cell pillar structures 118. Following the material removal process, an uppermost boundary (e.g., an upper surface, a top surface) of a remaining portion of the doped semiconductor material 108 may be vertically positioned (e.g., in the Z-direction) at or below uppermost boundaries of the cell pillar structures 118. For example, as shown in FIG. 1D, the uppermost boundary of the remaining portion of the doped semiconductor material 108 may vertically underlie an uppermost boundary of the outer material stack 120 of respective cell pillar structures 118. In some embodiments, the uppermost boundary of the remaining portion of the doped semiconductor material 108 is vertically positioned at or above an uppermost boundary of the channel material 122 of respective cell pillar structures 118. In additional embodiments, the uppermost boundary of the remaining portion of the doped semiconductor material 108 is vertically positioned below the uppermost boundary of the channel material 122 of respective cell pillar structures 118. As a non-limiting example, the uppermost boundary of the remaining portion of the doped semiconductor material 108 may be positioned vertically between uppermost boundaries of the channel material 122 of the cell pillar structures 118 and uppermost boundaries of the fill material 124 of the cell pillar structures 118. As another non-limiting example, the uppermost boundary of the remaining portion of the doped semiconductor material 108 may be vertically positioned below the uppermost boundaries of the fill material 124 of the cell pillar structures 118.

The base structure 102 (FIG. 1C), the first isolation material 106 (FIG. 1C), and the upper portion of the doped semiconductor material 108 may be removed using one or more of at least one abrading process (e.g., at least one CMP process) and at least one etching process (e.g., at least one wet etching process and/or at least one dry etching process). In some embodiments, the base structure 102 (FIG. 1C) and the first isolation material 106 (FIG. 1C) are removed through a first material removal process (e.g., a first CMP process, a first etching process), and then the upper portion of the doped semiconductor material 108 is removed through a second material removal process (e.g., a second CMP process, a second etching process).

Referring next to FIG. 1E, an upper portion of the outer material stack 120 of respective cell pillar structures 118 may be removed (e.g., de-capped) to expose an upper portion of the channel material 122 of the respective cell pillar structures 118. As shown in FIG. 1E, for an individual cell pillar structure 118, the additional material removal process may substantially remove the outer material stack 120 from both an upper surface (e.g., a top surface) and upper portions of outer sidewall(s) (e.g., outer side surface(s)) of the channel material 122 of the cell pillar structure 118. The additional material removal process may form openings 162 horizontally surrounding and partially defined by the exposed upper portions of the outer sidewalls of the channel material 122 of the cell pillar structures 118. An individual opening 162 may have inner horizontal boundaries defined by the outer sidewall(s) of the channel material 122 of an individual cell pillar structure 118, outer horizontal boundaries at least partially defined by inner sidewall(s) (e.g., inner side surface(s)) of the remaining portion of the doped semiconductor material 108, and a lower vertical boundaries (e.g., a floor, a bottom) defined by an uppermost surface (e.g., a top surface) of a remaining portion of the outer material stack 120 of the cell pillar structure 118.

An individual opening 162 may be formed to have a vertical height H₁ (e.g., a vertical depth) from an uppermost boundary (e.g., an uppermost surface) of the remaining portion of the doped semiconductor material 108. The vertical height H₁ of an individual opening 162 may, for example, be less than or equal to a combined vertical height of the remaining portion of the doped semiconductor material 108 and the insulative structure(s) 112 vertically interposed between the remaining portion of the doped semiconductor material 108 and the first conductive structure(s) 114A (e.g., source-side GG structures) of the stack structure 110. In some embodiments, the vertical height H₁ of an individual opening 162 is within a range of from about 10 nanometers (nm) to about 50 nm, such as from about 15 nm to about 45 nm, or from about 30 nm to about 45 nm. A lower vertical boundary of an individual opening 162 (and, hence, an uppermost surface of a remaining portion of the outer material stack 120 of an individual cell pillar structure 118 defining the lower vertical boundary of the opening 162) may be located above, at, or below a lower vertical boundary (e.g., a lower surface) of the remaining portion of the doped semiconductor material 108. As shown in FIG. 1E, in some embodiments, the lower vertical boundary of an individual opening 162 is vertically positioned between an upper vertical boundary (e.g., an upper surface) and the lower vertical boundary of the remaining portion of the doped semiconductor material 108. In additional embodiments, an individual opening 162 is formed to vertically extend relatively deeper, such as to a lower vertical boundary within the range of the dashed box B depicted in FIG. 1E. For example, the lower vertical boundary of an individual opening 162 may be formed to be vertically positioned at the lower vertical boundary of the remaining portion of the doped semiconductor material 108. As another example, the lower vertical boundary of an individual opening 162 may be formed to be positioned vertically between an upper vertical boundary (e.g., an upper surface) and a lower vertical boundary (e.g., a lower surface) of the insulative structure(s) 112 vertically interposed between the doped semiconductor material 108 and the first conductive structure(s) 114A of the stack structure 110. As an additional example, the lower vertical boundary of an individual opening 162 may be formed to be vertically positioned at the lower vertical boundary of the insulative structure(s) 112 vertically interposed between the doped semiconductor material 108 and the first conductive structure(s) 114A of the stack structure 110.

Removing the upper portion of the outer material stack 120 of respective cell pillar structures 118 may facilitate relatively enhanced source-side GG, which may, for example, promote improved erase performance during use and operation of a microelectronic device (e.g., a memory device, such as a 3D NAND Flash memory device) of the disclosure relative to conventional microelectronic device configurations.

Referring next to FIG. 1F, additional doped semiconductor material 164 may be formed on the remaining portion of the doped semiconductor material 108 and on upper portions of the channel material 122 of the cell pillar structures 118 to form a microelectronic device 166 configured for source-side GIDL-assisted erase operations on the vertically extending strings of memory cells 126. The additional doped semiconductor material 164 may include a first portion 164A horizontally extending over and substantially covering upper surfaces (e.g., top surfaces) of the remaining portion of the doped semiconductor material 108 and the cell pillar structures 118, and second portions 164B vertically projecting from the first portion 164A and substantially filling the openings 162 (FIG. 1E). Geometric configurations of the second portions 164B of the additional doped semiconductor material 164 may be substantially the same as those of the openings 162 (FIG. 1E). For example, an individual second portion 164B may have inner sidewall(s) defined by the outer sidewall(s) of the channel material 122 of an individual cell pillar structure 118, outer sidewall(s) at least partially defined by inner sidewall(s) of the remaining portion of the doped semiconductor material 108, and a lower vertical boundary (e.g., a floor, a bottom) defined by an uppermost surface (e.g., a top surface) of a remaining portion of the outer material stack 120 of the cell pillar structure 118. Accordingly, as shown in FIG. 1F, a lower boundary of the additional doped semiconductor material 164 may have a non-planar geometry corresponding to (e.g., mirroring) a topography at least partially defined by the remaining portions of the cell pillar structures 118 and the doped semiconductor material 108. In addition, an upper boundary of the additional doped semiconductor material 164 may be formed to be substantially planar.

The additional doped semiconductor material 164 may be formed of and include semiconductor material doped (e.g., impregnated) with one or more conductivity enhancing species (e.g., one or more N-type dopants, one or more P-type dopants). In some embodiments, the additional doped semiconductor material 164 is formed of and includes polycrystalline silicon (also referred to herein as “polysilicon”) doped (e.g., relatively highly doped) with at least one N-type dopant (e.g., one or more of phosphorus, arsenic, antimony, and bismuth). For example, the doped semiconductor material 108 may be formed of and include N+ polysilicon. In additional embodiments, the additional doped semiconductor material 164 is formed of and includes polycrystalline silicon doped (e.g., relatively highly doped) with at least one P-type dopant (e.g., one or more of boron, aluminum, and gallium). A material composition of the additional doped semiconductor material 164 may be substantially the same as a material composition of the doped semiconductor material 108, or the material composition of the additional doped semiconductor material 164 may be different than the material composition of the doped semiconductor material 108. In some embodiments, the material composition of the additional doped semiconductor material 164 is substantially the same as the material composition of the doped semiconductor material 108. For example, the additional doped semiconductor material 164 and the doped semiconductor material 108 may each be formed of and include N+ polysilicon.

Optionally, the additional doped semiconductor material 164 and the remaining portion of the doped semiconductor material 108 may be annealed (e.g., laser annealed, thermally annealed) after the formation of the additional doped semiconductor material 164. Annealing the additional doped semiconductor material 164 and the remaining portion of the doped semiconductor material 108 may, for example, enhance dopant activation therein and/or may enhance desirable junction surface characteristics (e.g., junction surface smoothness) for the additional doped semiconductor material 164.

The configuration of the microelectronic device 166 facilitates GIDL-assisted erase operations on the vertical extending strings of memory cells 126 thereof while also permitting the control logic region 140 thereof to be positioned vertically under the memory array region 104 thereof. The configuration of the microelectronic device 166 may facilitate relatively relaxed margins for SGS structure and SGD structure on current (Iₒₙ) and off current (I_{off}), and relatively reduced SGS and SGD trapping during erase operations as compared to many conventional microelectronic device configurations. Accordingly, the microelectronic device 166 may have a so-called CMOS under array (“CuA”) configuration (or a so-called CMOS above array (“CaA”) configuration) or a so-called CMOS bonded array (“CBA”) configuration rather the so-called CMOS outside array (“CoA”) configurations exhibited by many conventional microelectronic devices.

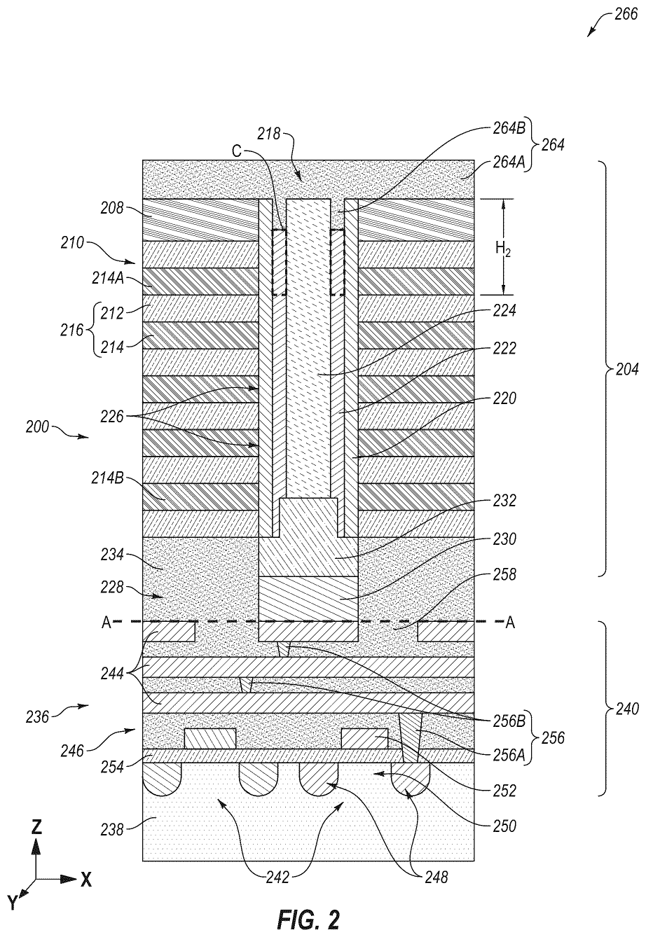

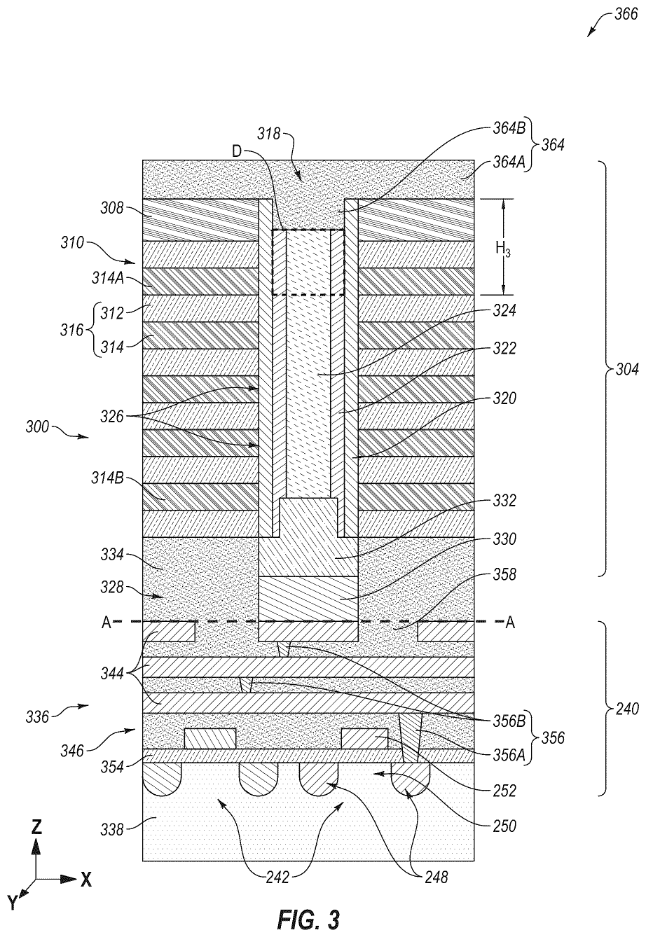

In additional embodiments, some of the processing acts and stages previously described herein with reference to FIGS. 1A through IF may modified to form additional microelectronic devices of the disclosure having different configurations than the microelectronic device 166 (FIG. 1F). For example, FIGS. 2 and 3 are simplified, partial vertical cross-sectional views of a microelectronic device 266 (FIG. 2) and a microelectronic device 366 (FIG. 3) formed in accordance with an additional methods of the disclosure. The method of forming the microelectronic device 266 (FIG. 2) and the method of forming the microelectronic device 366 (FIG. 3) may include the processing acts and processing stages previously described herein with reference to FIGS. 1A through ID, but processing acts and stages following the processing previously described herein with reference to FIG. 1D may be modified relative to the processing previously described herein with reference to FIGS. 1E and 1F.

It will be understood that throughout FIGS. 2 and 3 and the associated description, features (e.g., regions, sections, structures, circuitry, devices) functionally similar to respective features previously described with reference to one or more of FIGS. 1A through IF are referred to with similar reference numerals incremented by 100. To avoid repetition, not all features shown in FIGS. 2 and 3 are described in detail herein. Rather, unless described otherwise below, a feature in one or more of FIGS. 2 and 3 designated by a reference numeral that is a 100 increment of the reference numeral of a feature previously described with reference to one or more of FIGS. 1A through IF will be understood to be substantially similar to and have substantially the same advantages as the previously described feature. As a non-limiting example, in FIGS. 2 and 3, a stack structure 210 (FIG. 2) and a stack structure 310 (FIG. 3) may respectively be substantially similar to the stack structure 110 previously described herein with reference to one or more of FIGS. 1A and 1C through 1F. As another non-limiting example, in FIGS. 2 and 3, a second microelectronic device structure 236 (FIG. 2) and a second microelectronic device structure 336 (FIG. 3) may respectively be substantially similar to the second microelectronic device structure 136 previously described herein with reference to one or more of FIGS. 1B through 1F.

Referring to FIG. 2, the microelectronic device 266 may be formed to include different configurations of the cell pillar structures 218 and the additional doped semiconductor material 264 thereof as compared to respective configurations of the cell pillar structures 118 (FIG. 1F) and the additional doped semiconductor material 164 (FIG. 1F) of the microelectronic device 166 (FIG. 1F). For example, the material removal process previously described with reference to FIG. 1E may be modified such that upper portions of the channel material 222 of the cell pillar structures 218 on outer sidewalls of the fill material 224 of the cell pillar structures 218 are removed instead of the upper portions of the outer material stacks 220 of the cell pillar structures 218 on the outer sidewalls of the channel material 222 of the cell pillar structures 218. Accordingly, configurations of the channel material 222 of the cell pillar structures 218, the outer material stacks 220 of the cell pillar structures 218, and the second portions 264A of the additional doped semiconductor material 264 of the microelectronic device 266 may be different than the respective configurations of the channel material 122 (FIG. 1F) of the cell pillar structures 118 (FIG. 1F), the outer material stack 120 (FIG. 1F) of the cell pillar structures 118 (FIG. 1F), and the second portions 164B (FIG. 1F) of the additional doped semiconductor material 164 (FIG. 1F) of the microelectronic device 166 (FIG. 1F).

Following the processing stage previously described with reference to FIG. 1D, upper portions of the channel material 222 of the cell pillar structures 218 on outer sidewalls of the fill material 224 of the cell pillar structures 218 may be removed while substantially maintaining upper portions of the outer material stacks 220 of the cell pillar structures 218 on inner sidewalls of the remaining portion of the doped semiconductor material 208. As a result, openings (e.g., corresponding to the openings 162 (FIG. 1E)) formed through the material removal process, as well as the second portions 264B of the additional doped semiconductor material 264 subsequently formed within the openings, may be horizontally interposed between the fill material 224 of the cell pillar structures 218 and the outer material stacks 220 of the cell pillar structures 218. In addition, as described in further detail below, a vertical height H₂ of the aforementioned openings and the second portions 264B of the additional doped semiconductor material 264 may, optionally, be different that the vertical height H₁ (FIGS. 1E and 1F) of the openings 162 (FIG. 1E) and the second portions 164B (FIG. 1F) of the additional doped semiconductor material 164 (FIG. 1F).

The vertical height H₂ of the second portions 264B of the additional doped semiconductor material 264 (and, hence, the openings filled thereby) from an uppermost boundary (e.g., an uppermost surface) of the remaining portion of the doped semiconductor material 208 may be less than or equal to a combined vertical height of the remaining portion of the doped semiconductor material 208, the first conductive structure(s) 214A (e.g., source-side GG structures) of the stack structure 210, and the insulative structure(s) 212 of the stack structure 210 vertically interposed between the remaining portion of the doped semiconductor material 208 and the first conductive structure(s) 214A of the stack structure 210. In some embodiments, the vertical height H₂ of the second portions 264B of the additional doped semiconductor material 264 is within a range of from about 10 nm to about 95 nm, such as from about 15 nm to about 90 nm, from about 30 nm to about 90 nm, from about 45 nm to about 90 nm, or from about 60 nm to about 90 nm. A lower vertical boundary of an individual second portion 264B of the additional doped semiconductor material 264 (and, hence, an uppermost surface of a remaining portion of the channel material 222 of an individual cell pillar structure 218 defining the lower vertical boundary of the second portion 264B of the additional doped semiconductor material 264) may be located above, at, or below a lower vertical boundary (e.g., a lower surface) of the remaining portion of the doped semiconductor material 208. As shown in FIG. 2, in some embodiments, the lower vertical boundary of an individual second portion 264B of the additional doped semiconductor material 264 is vertically positioned between an upper vertical boundary (e.g., an upper surface) and the lower vertical boundary of the remaining portion of the doped semiconductor material 208. In additional embodiments, an individual second portion 264B of the additional doped semiconductor material 264 is formed to vertically extend relatively deeper, such as to a lower vertical boundary within the range of the dashed box C depicted in FIG. 2. For example, the lower vertical boundary of an individual second portion 264B of the additional doped semiconductor material 264 may be formed to be vertically positioned at the lower vertical boundary of the remaining portion of the doped semiconductor material 208. As another example, the lower vertical boundary of an individual second portion 264B of the additional doped semiconductor material 264 may be formed to be vertically positioned between an upper vertical boundary (e.g., an upper surface) and a lower vertical boundary (e.g., a lower surface) of the insulative structure(s) 212 vertically interposed between the remaining portion of the doped semiconductor material 208 and the first conductive structure(s) 214A of the stack structure 210. As an additional example, the lower vertical boundary of an individual second portion 264B of the additional doped semiconductor material 264 may be formed to be vertically positioned between an upper vertical boundary (e.g., an upper surface) and a lower vertical boundary (e.g., a lower surface) of the first conductive structure(s) 214A of the stack structure 210. As a further example, the lower vertical boundary of an individual second portion 264B of the additional doped semiconductor material 264 may be formed to be vertically positioned at the lower vertical boundary of the first conductive structure(s) 214A of the stack structure 210.

The configuration of the microelectronic device 266 facilitates GIDL-assisted erase operations on the vertical extending strings of memory cells 226 thereof while also permitting the control logic region 240 thereof to be positioned vertically under the memory array region 204 thereof. The configuration of the microelectronic device 266 may facilitate relatively relaxed margins for SGS structure and SGD structure on current (Iₒₙ) and off current (I_{off}), and relatively reduced SGS and SGD trapping during erase operations as compared to many conventional microelectronic device configurations. Accordingly, the microelectronic device 266 may have CuA configuration (or a CaA configuration) rather the CoA configurations exhibited by many conventional microelectronic devices.

Referring to FIG. 3, the microelectronic device 366 may also be formed to include different configurations of the cell pillar structures 318 and the additional doped semiconductor material 364 thereof as compared to respective configurations of the cell pillar structures 118 (FIG. 1F) and the additional doped semiconductor material 164 (FIG. 1F) of the microelectronic device 166 (FIG. 1F). For example, the material removal process previously described with reference to FIG. 1E may be modified such that upper portions of the channel material 322 and the fill material 324 are removed instead of the upper portions of the outer material stacks 320 of the cell pillar structures 318 on the outer sidewalls of the channel material 322 of the cell pillar structures 318. Accordingly, configurations of the channel material 322 of the cell pillar structures 318, the fill material 324 of the cell pillar structures 318, the outer material stacks 320 of the cell pillar structures 318, and the second portions 364A of the additional doped semiconductor material 364 of the microelectronic device 366 may be different than the respective configurations of the channel material 122 (FIG. 1F) of the cell pillar structures 118 (FIG. 1F), the fill material 124 (FIG. 1F) of the cell pillar structures 118 (FIG. 1F), the outer material stack 120 (FIG. 1F) of the cell pillar structures 118 (FIG. 1F), and the second portions 164B (FIG. 1F) of the additional doped semiconductor material 164 (FIG. 1F) of the microelectronic device 166 (FIG. 1F).

Following the processing stage previously described with reference to FIG. 1D, upper portions of the channel material 322 and the fill material 324 of the cell pillar structures 318 of the cell pillar structures 318 may be removed while substantially maintaining upper portions of the outer material stacks 320 of the cell pillar structures 318 on inner sidewalls of the remaining portion of the doped semiconductor material 308. As a result, openings (e.g., corresponding to the openings 162 (FIG. 1E)) formed through the material removal process, as well as the second portions 364B of the additional doped semiconductor material 364 subsequently formed with the openings, may be horizontally interposed between opposing upper portions of the outer material stacks 320 of the cell pillar structures 318. In addition, as described in further detail below, a vertical height H₃ of the aforementioned openings and the second portions 364B of the additional doped semiconductor material 364 may, optionally, be different that the vertical height H₁ (FIGS. 1E and 1F) of the openings 162 (FIG. 1E) and the second portions 164B (FIG. 1F) of the additional doped semiconductor material 164 (FIG. 1F).

The vertical height H₃ of the second portions 364B of the additional doped semiconductor material 364 (and, hence, the openings filled thereby) from an uppermost boundary (e.g., an uppermost surface) of the remaining portion of the doped semiconductor material 308 may be less than or equal to a combined vertical height of the remaining portion of the doped semiconductor material 308, the first conductive structure(s) 314A (e.g., source-side GG structures) of the stack structure 310, and the insulative structure(s) 312 of the stack structure 310 vertically interposed between the remaining portion of the doped semiconductor material 308 and the first conductive structure(s) 314A of the stack structure 310. In some embodiments, the vertical height H₃ of the second portions 364B of the additional doped semiconductor material 364 is within a range of from about 10 nm to about 95 nm, such as from about 15 nm to about 90 nm, from about 30 nm to about 90 nm, from about 45 nm to about 90 nm, or from about 60 nm to about 90 nm. A lower vertical boundary of an individual second portion 364B of the additional doped semiconductor material 364 (and, hence, an uppermost surface of a remaining portion of the channel material 322 of an individual cell pillar structure 318 defining the lower vertical boundary of the second portion 364B of the additional doped semiconductor material 364) may be located above, at, or below a lower vertical boundary (e.g., a lower surface) of the remaining portion of the doped semiconductor material 308. As shown in FIG. 3, in some embodiments, the lower vertical boundary of an individual second portion 364B of the additional doped semiconductor material 364 is vertically positioned between an upper vertical boundary (e.g., an upper surface) and the lower vertical boundary of the remaining portion of the doped semiconductor material 308. In additional embodiments, an individual second portion 364B of the additional doped semiconductor material 364 is formed to vertically extend relatively deeper, such as to a lower vertical boundary within the range of the dashed box D depicted in FIG. 3. For example, the lower vertical boundary of an individual second portion 364B of the additional doped semiconductor material 364 may be formed to be vertically positioned at the lower vertical boundary of the remaining portion of the doped semiconductor material 308. As another example, the lower vertical boundary of an individual second portion 364B of the additional doped semiconductor material 364 may be formed to be vertically positioned between an upper vertical boundary (e.g., an upper surface) and a lower vertical boundary (e.g., a lower surface) of the insulative structure(s) 312 vertically interposed between the remaining portion of the doped semiconductor material 308 and the first conductive structure(s) 314A of the stack structure 310. As an additional example, the lower vertical boundary of an individual second portion 364B of the additional doped semiconductor material 364 may be formed to be vertically positioned between an upper vertical boundary (e.g., an upper surface) and a lower vertical boundary (e.g., a lower surface) of the first conductive structure(s) 314A of the stack structure 310. As a further example, the lower vertical boundary of an individual second portion 364B of the additional doped semiconductor material 364 may be formed to be vertically positioned at the lower vertical boundary of the first conductive structure(s) 314A of the stack structure 310.

The configuration of the microelectronic device 366 facilitates GIDL-assisted erase operations on the vertical extending strings of memory cells 326 thereof while also permitting the control logic region 340 thereof to be positioned vertically under the memory array region 304 thereof. The configuration of the microelectronic device 366 may facilitate relatively relaxed margins for SGS structure and SGD structure on current (Iₒₙ) and off current (I_{off}), and relatively reduced SGS and SGD trapping during erase operations as compared to many conventional microelectronic device configurations. Accordingly, the microelectronic device 366 may have CuA configuration (or a CaA configuration) rather the CoA configurations exhibited by many conventional microelectronic devices.

Thus, a microelectronic device according to embodiments of the disclosure includes a stack structure, a cell pillar structure, doped semiconductor material, and control logic devices. The stack structure includes vertically neighboring tiers respectively including a conductive structure and an insulative structure vertically neighboring the conductive structure. The cell pillar structure vertically extends through the stack structure and includes a fill material, a channel material horizontally surrounding the fill material, and an outer material stack horizontally surrounding the channel material. The doped semiconductor material vertically overlies the stack structure and includes a first portion substantially continuously horizontally extending over the stack structure and the cell pillar structure, and a second portion vertically projecting from the first portion and in physical contact with the channel material of the cell pillar structure. The control logic devices vertically underlie and are coupled to the cell pillar structures.

Furthermore, in accordance with embodiments of the disclosure, a method of forming microelectronic device includes forming a first microelectronic device structure comprising control logic devices. A second microelectronic device structure is formed and includes a base structure, a doped semiconductor material overlying the base structure, a stack structure overlying the doped semiconductor material and comprising conductive structures and insulating structures vertically alternating with the conductive structures, and a cell pillar structure vertically extending through the stack structure and into the doped semiconductor material. The cell pillar structure includes a channel material surrounded by an outer material stack. The second microelectronic device structure is bonded to the first microelectronic device structure to form an assembly. The base structure and an upper portion of the doped semiconductor material are removed. One of the channel material and the outer material stack of the cell pillar structure are vertically recessed relative to a remaining portion of the doped semiconductor material and an other of the channel material and the outer material stack to form an opening. Additional doped semiconductor material is formed to substantially fill the opening and to substantially continuously horizontally extend over the doped semiconductor material and a remainder of the cell pillar structure.

Moreover, a memory device according to embodiments of the disclosure includes a memory array region and a control logic region vertically underlying and horizontally overlapping the memory array region. The memory array region includes a stack structure, a cell pillar structure, doped semiconductor material, and additional doped semiconductor material. The stack structure includes a vertically alternating sequence of conductive structures and insulating structures. The cell pillar structure vertically extends through the stack structure and includes a channel material and an outer material stack horizontally interposed between the channel material and the stack structure. The doped semiconductor material vertically overlies the stack structure and horizontally surrounds an upper portion of the cell pillar structure. The additional doped semiconductor material is on upper surfaces of the doped semiconductor material and the channel material of the cell pillar structure, and sidewalls of one or more of the channel material of the cell pillar structure and the outer material stack of the cell pillar structure. The control logic region includes control logic circuitry in electrical communication with the cell pillar structure.

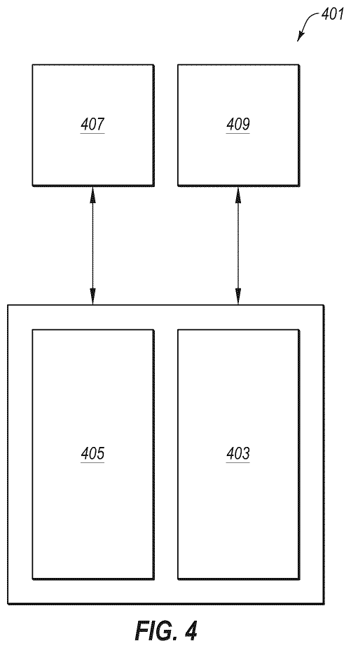

Microelectronic devices (e.g., the microelectronic device 166 (FIG. 1F), the microelectronic device 266 (FIG. 2), the microelectronic device 366 (FIG. 3)) in accordance with embodiments of the disclosure may be used in embodiments of electronic systems of the disclosure. For example, FIG. 4 is a block diagram of an illustrative electronic system 401 according to embodiments of disclosure. The electronic system 401 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, a navigation device, etc. The electronic system 401 includes at least one memory device 403. The memory device 403 may comprise, for example, a microelectronic device (e.g., the microelectronic device 166 (FIG. 1F), the microelectronic device 266 (FIG. 2), the microelectronic device 366 (FIG. 3)) previously described herein. The electronic system 401 may further include at least one electronic signal processor device 405 (often referred to as a “microprocessor”). The electronic signal processor device 405 may, optionally, include a microelectronic device (e.g., the microelectronic device 166 (FIG. 1F), the microelectronic device 266 (FIG. 2), the microelectronic device 366 (FIG. 3)) previously described herein. While the memory device 403 and the electronic signal processor device 405 are depicted as two (2) separate devices in FIG. 4, in additional embodiments, a single (e.g., only one) memory/processor device having the functionalities of the memory device 403 and the electronic signal processor device 405 is included in the electronic system 401. In such embodiments, the memory/processor device may include a microelectronic device (e.g., the microelectronic device 166 (FIG. 1F), the microelectronic device 266 (FIG. 2), the microelectronic device 366 (FIG. 3)) previously described herein. The electronic system 401 may further include one or more input devices 407 for inputting information into the electronic system 401 by a user, such as, for example, a mouse or other pointing device, a keyboard, a touchpad, a button, or a control panel. The electronic system 401 may further include one or more output devices 409 for outputting information (e.g., visual or audio output) to a user such as, for example, a monitor, a display, a printer, an audio output jack, a speaker, etc. In some embodiments, the input device 407 and the output device 409 may comprise a single touchscreen device that can be used both to input information to the electronic system 401 and to output visual information to a user. The input device 407 and the output device 409 may communicate electrically with one or more of the memory device 403 and the electronic signal processor device 405.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalent. For example, elements and features disclosed in relation to one embodiment may be combined with elements and features disclosed in relation to other embodiments of the disclosure.

What is claimed is:

1. A microelectronic device, comprising:
a stack structure comprising vertically neighboring tiers respectively comprising a conductive structure and an insulative structure vertically neighboring the conductive structure;
a cell pillar structure vertically extending through the stack structure and comprising:
a fill material;
a channel material horizontally surrounding the fill material; and
an outer material stack horizontally surrounding the channel material;
doped semiconductor material vertically overlying the stack structure and comprising:
a first portion substantially continuously horizontally extending over the stack structure and the cell pillar structure; and
a second portion vertically projecting from the first portion and in physical contact with the channel material of the cell pillar structure; and
control logic devices vertically underlying and coupled to the cell pillar structure.

2. The microelectronic device of claim 1, wherein:
the first portion of the doped semiconductor material physically contacts an uppermost surface of the channel material of the cell pillar structure;
the second portion of the doped semiconductor material physically contacts each of:
an outer sidewall of the channel material of the cell pillar structure; and
an uppermost surface of the outer material stack of the cell pillar structure.

3. The microelectronic device of claim 2, wherein a lowermost boundary of the second portion of the doped semiconductor material is vertically positioned at or above an uppermost boundary of the conductive structure of an uppermost tier of the vertically neighboring tiers of the stack structure.

4. The microelectronic device of claim 2, wherein the second portion of the doped semiconductor material vertically extends into the stack structure.

5. The microelectronic device of claim 1, wherein:
the first portion of the doped semiconductor material physically contacts each of:
an uppermost surface of the fill material of the cell pillar structure; and
an uppermost surface of the outer material stack of the cell pillar structure; and
the second portion of the doped semiconductor material physically contacts each of:
an outer sidewall of the fill material of the cell pillar structure;
an uppermost surface of the channel material of the cell pillar structure; and
an inner sidewall of the outer material stack of the cell pillar structure.

6. The microelectronic device of claim 5, wherein a lowermost boundary of the second portion of the doped semiconductor material is vertically positioned at or above a lowermost boundary of the conductive structure of an uppermost tier of the vertically neighboring tiers of the stack structure.

7. The microelectronic device of claim 5, wherein the second portion of the doped semiconductor material vertically overlaps the conductive structure of an uppermost one of the vertically neighboring tiers of the stack structure.

8. The microelectronic device of claim 1, wherein:
the first portion of the doped semiconductor material physically contacts an uppermost surface of the outer material stack of the cell pillar structure; and
the second portion of the doped semiconductor material physically contacts each of:
an uppermost surface of the fill material of the cell pillar structure;
an uppermost surface of the channel material of the cell pillar structure; and
an inner sidewall of the outer material stack of the cell pillar structure.

9. The microelectronic device of claim 8, wherein a lowermost boundary of the second portion of the doped semiconductor material is vertically positioned at or above a lowermost boundary of the conductive structure of an uppermost tier of the vertically neighboring tiers of the stack structure.

10. The microelectronic device of claim 1, further comprising additional doped semiconductor material horizontally neighboring the cell pillar structure and vertically extending from and between the doped semiconductor material and the stack structure.

11. The microelectronic device of claim 1, wherein the doped semiconductor material comprises annealed, N+ polysilicon.

12. A method of forming a microelectronic device, comprising:
forming a first microelectronic device structure comprising control logic devices;
forming a second microelectronic device structure comprising:
a base structure;
a doped semiconductor material overlying the base structure;
a stack structure overlying the doped semiconductor material and comprising conductive structures and insulating structures vertically alternating with the conductive structures; and
a cell pillar structure vertically extending through the stack structure and into the doped semiconductor material, the cell pillar structure comprising a channel material surrounded by an outer material stack;
bonding the second microelectronic device structure to the first microelectronic device structure to form an assembly;
removing the base structure and an upper portion of the doped semiconductor material;
vertically recessing one of the channel material and the outer material stack of the cell pillar structure relative to a remaining portion of the doped semiconductor material and an other of the channel material and the outer material stack to form an opening; and
forming additional doped semiconductor material substantially filling the opening and substantially continuously horizontally extending over the doped semiconductor material and a remainder of the cell pillar structure.

13. The method of claim 12, wherein forming the second microelectronic device structure comprises forming the second microelectronic device structure to be free of a conductive lateral contact structure vertically interposed between the stack structure and the doped semiconductor material and horizontally extending through the outer material stack of the cell pillar structure and contacting the channel material of the cell pillar structure.

14. The method of claim 12, wherein bonding the second microelectronic device structure to the first microelectronic device structure comprises:
vertically inverting one of the second microelectronic device structure and the first microelectronic device structure relative to an other of the second microelectronic device structure and the first microelectronic device structure; and
bonding the second microelectronic device structure to the first microelectronic device structure through one or more of oxide-to-oxide bonds and metal-to-metal bonds.

15. The method of claim 12, wherein vertically recessing one of the channel material and the outer material stack of the cell pillar structure comprises vertically recessing the outer material stack of the cell pillar structure, the opening horizontally interposed between the channel material of the cell pillar structure and the remaining portion of the doped semiconductor material.

16. The method of claim 15, wherein vertically recessing the outer material stack of the cell pillar structure comprises forming the opening to vertically extend below a lower boundary of the doped semiconductor material.

17. The method of claim 12, wherein vertically recessing one of the channel material and the outer material stack of the cell pillar structure comprises vertically recessing the channel material of the cell pillar structure, the opening horizontally interposed between the outer material stack of the cell pillar structure and a dielectric fill material of the cell pillar structure.

18. The method of claim 17, wherein vertically recessing the outer material stack of the cell pillar structure comprises forming the opening to vertically extend below a lower boundary of an uppermost one of the insulating structures of the stack structure.

19. The method of claim 12, wherein vertically recessing one of the channel material and the outer material stack of the cell pillar structure comprises vertically recessing each of the channel material of the cell pillar structure and a dielectric fill material of the cell pillar structure relative to the outer material stack of the cell pillar structure.

20. A memory device, comprising:
a memory array region comprising:
a stack structure comprising a vertically alternating sequence of conductive structures and insulating structures;
a cell pillar structure vertically extending through the stack structure and comprising a channel material and an outer material stack horizontally interposed between the channel material and the stack structure;
doped semiconductor material vertically overlying the stack structure and horizontally surrounding an upper portion of the cell pillar structure;
additional doped semiconductor material on:
upper surfaces of the doped semiconductor material and the channel material of the cell pillar structure; and
sidewalls of one or more of the channel material of the cell pillar structure and the outer material stack of the cell pillar structure; and
a control logic region vertically underlying and horizontally overlapping the memory array region, the control logic region comprising control logic circuitry in electrical communication with the cell pillar structure.
